(19) United States
(12) Patent Application Publication
(10) Pub. No.: US 2017/0221956 A1
(43) Pub. Date: Aug. 3, 2017

(54) SOLID-STATE IMAGING DEVICE AND IMAGING APPARATUS

(71) Applicant: OLYMPUS CORPORATION, Tokyo (JP)

(72) Inventor: Mitsuhiro Tsukimura, Tokyo (JP)

(73) Assignee: OLYMPUS CORPORATION, Tokyo (JP)

(21) Appl. No.: 15/490,493

(22) Filed: Apr. 18, 2017

Related U.S. Application Data
(63) Continuation of application No. PCT/JP2014/084142, filed on Dec. 24, 2014.

(51) Int. Cl. H01L 27/146; H04N 9/04; H04N 5/369

(52) U.S. Cl. CPC H01L 27/14647; H01L 27/14627; H01L 27/14623; H01L 27/14621; H01L 27/14636; H01L 27/14605; H04N 5/369; H04N 9/045

(57) ABSTRACT

A solid-state imaging device has a first substrate and a second substrate. The first substrate has a plurality of first photoelectric conversion units. The second substrate has a second semiconductor layer. The second semiconductor layer has a plurality of second photoelectric conversion units. A first dimension of a first range is smaller than a second dimension of a second range. The first range is the entirety of the second photoelectric conversion unit. The first dimension is a dimension of the first range in a direction parallel to a main surface of the second substrate. The second range is a range in which the second light is incident in the second semiconductor layer. The second dimension is a dimension of the second range in the direction parallel to the main surface of the second substrate.

### BACKGROUND OF THE INVENTION

Field of the Invention

The present invention relates to a solid-state imaging device and an imaging apparatus having a structure in which a plurality of substrates is laminated.

Priority is claimed on International Patent Application PCT/JP2014-084142, filed on Dec. 24, 2014, the content of Which is incorporated herein by reference.

Description of Related Art

There is disclosed a solid-state imaging device having a plurality of substrates. For example, a solid-state imaging device, in which a first substrate and a second substrate are laminated, is disclosed in Japanese Unexamined Patent Application Publication No. 2013-70030. In the solid-state imagine device disclosed in Japanese Unexamined Patent Application Publication No. 2013-70030, a plurality of pixels is arranged on each of the first substrate and the second substrate. Hence, the resolution of the captured image signal is improved.

An example of the solid-state imaging device having the plurality of substrates will be described. FIG. 9 shows a configuration of a solid-state imaging device 1000. FIG 9 shows a cross-section of the solid-state imaging device 1000. As shown in FIG. 9, the solid-state imaging device 1000 has a first substrate 70, a second substrate 80, microlenses 901, and color filters 902. The first substrate 70 and the second substrate 80 are laminated.

The color filters 902 are disposed on a main surface (the largest surface among the plurality of surfaces constituting a surface of the substrate) of the first substrate 70, and the microlenses 901 are disposed on the color filters 902. Although there is a plurality of microlenses 901 in FIG. 9, the reference sign of one microlens 901 is shown as a representative thereof. Further, although there is a plurality of color filters 902 in FIG. 9, the reference sign of one color filter 902 is shown as a representative thereof.

Light, which is emitted from a subject and is transmitted through an imaging lens disposed on an optically front side of the solid-state imaging device 1000, is incident into the microlenses 901. The microlenses 901 forms an image of the light transmitted through the imaging lens. The color filters 902 transmit light with wavelengths corresponding to predetermined colors.

The first substrate 70 has a first semiconductor layer 700 and a first wiring layer 710. The first semiconductor layer 700 has first photoelectric conversion units 701. Although there is a plurality of first photoelectric conversion units 701 in FIG. 9, the reference sign of one first photoelectric conversion unit 701 is shown as a representative thereof. The first photoelectric conversion units 701 convert the incident light into a signal.

A first wiring layer 710 includes first wires 711 and a first interlayer insulation film 712. Although there is a plurality of first wires 711 in FIG. 9, the reference sign of one first wire 711 is shown as a representative thereof.

The first wires 711 are a thin film on which a wiring pattern is formed. The first wires 711 transmit the signals generated by the first photoelectric conversion units 701 and other signals (a power supply voltage, a ground voltage, and the like). In the example shown in FIG. 9, three layers of the first wires 711 are formed. In the first wiring layer 710, a part other than the first wires 711 is formed of a first interlayer insulation film 712.

The second substrate 80 has a second semiconductor layer 800 and a second wiring layer 810. The second semiconductor layer 800 has second photoelectric conversion units 801. Although there is a plurality of second photoelectric conversion units 801 in FIG. 9, the reference sign of one second photoelectric conversion unit 801 is shown as a representative thereof. The second photoelectric conversion units 801 convert the incident light into a signal.

A second wiring layer 810 includes second wires 811 and a second interlayer insulation film 812. Although there is a plurality of second wires 811 in FIG. 9, the reference sign of one second wire 811 is shown as a representative thereof.

The second wires 811 are a thin film on which a wiring pattern is formed. The second wires 811 transmit the signals generated by the second photoelectric conversion units 801 and other signals (a power supply voltage, a ground voltage, and the like). In the example shown in FIG. 9, three layers of the second wires 811 are formed. In the second wiring layer 810, a part other than the second wires 811 is formed of the second interlayer insulation film 812.

The first substrate 70 and the second substrate 80 are electrically connected at the interface between the first substrate 70 and the second substrate 80. The first photoelectric conversion units 701 may acquire captured image signals, and the second photoelectric conversion units 801 may acquire focus detection signals.

In fabrication of the solid-state imaging device 1000, when the first substrate 70 and the second substrate 80 are bonded to each other, positional deviation may occur between the first substrate 70 and the second substrate 80. FIG. 10 shows a state in which the positional deviation between the first substrate 70 and the second substrate 80 occurs in the solid-state imaging device 1000 shown in FIG. 9. In FIG. 10, the second substrate 80 deviates to the right with respect. to the first substrate 70.

The light transmitted through the microlenses 901 passes through the color filters 902. The light transmitted through the color filters 902 is incident onto the first semiconductor layer 700. The light incident onto the first semiconductor layer 700 travels through the first semiconductor layer 700, and is incident into the first photoelectric conversion units 701. The light transmitted through the first photoelectric conversion units 701 passes through the first wiring layer 710 and the second wiring layer 810. The light transmitted through the second wiring layer 810 is incident into second ranges R102 of the second semiconductor layer 800. The light incident into the second ranges R102 is incident into first ranges R101 of the second photoelectric conversion units 801. The dimension of the second photoelectric conversion unit 801 in the direction parallel to the main surface of the second substrate 80 is approximately equal to the dimension of the first photoelectric conversion unit 701 in the direction parallel to the main surface of the first substrate 70.

Each first range R101 is a range in which light is incident into the second photoelectric conversion unit 201. Although there is a plurality of first ranges R101 in FIG. 10, the reference sign of one first range R101 is shown as a representative thereof. Each second range R102 is a range in which light is incident in the second semiconductor layer 800. Although there is a plurality of second ranges R102 in FIG. 10, the reference sign of one second range R102 is shown as a representative thereof.

In a case where there is no positional deviation between the first substrate 70 and the second substrate 80, the following condition is satisfied. In a case where the plurality of first photoelectric conversion units 701 and the plurality of second photoelectric conversion units 801 are viewed in the direction perpendicular to the main surface of the first substrate 70 or the second substrate 80, the respective centers of the plurality of first photoelectric conversion units 701 substantially coincide with the respective centers of the plurality of second photoelectric conversion units 801. Further, in a case where the plurality of second photoelectric conversion units 801 and the plurality of second ranges R102 are viewed in the direction perpendicular to the main surface of the second substrate 80, the respective centers of the plurality of second photoelectric conversion units 801 substantially coincide with the respective centers of the plurality of second ranges R102.

In FIG. 10, there is positional deviation between the first substrate 70 and the second substrate 80. In FIG. 10, in a case where the plurality of first photoelectric conversion units 701 and the plurality of second photoelectric conversion units 801 are viewed in the direction perpendicular to the main surface of the first substrate 70 or the second substrate 80, the respective centers of the plurality of the first photoelectric conversion units 701 do not coincide with the respective centers of the plurality of second photoelectric conversion units 801. Further, in FIG. 10, in a case where the plurality of second photoelectric conversion units 801 and the plurality of second ranges R102 are viewed in the direction perpendicular to the main surface of the second substrate 80, the respective centers of the plurality of second photoelectric conversion units 801 do not coincide with the respective centers of the plurality of second ranges R102.

In a case where there is small positional deviation between the first substrate 70 and the second substrate 80, most of the light transmitted through the first photoelectric conversion units 701 is incident into the second photoelectric conversion units 801. However, as shown in FIG. 10, in a case where there is large positional deviation between the first substrate 70 and the second substrate 80, the second wires 811 overlap with the optical path of the light transmitted through the first photoelectric conversion units 701. Hence, a part of light is blocked by the second wires 811. As a result, a part of light is not incident into the second photoelectric conversion units 801.

### SUMMARY OF THE INVENTION

According to a first aspect of the present invention, a solid-state imaging device comprises a first substrate and a second substrate. The first substrate has a plurality of first photoelectric conversion units into which first light is incident. The plurality of first photoelectric conversion units converts the first light into a signal. The second substrate has a second semiconductor layer onto which second light is incident. The second semiconductor layer has a plurality of second photoelectric conversion units into which the second light incident onto the second semiconductor layer is incident. The plurality of second photoelectric conversion units converts the second light into a signal. The second light is the first light transmitted through the plurality of first photoelectric conversion units. A first dimension of a first range is smaller than a second dimension of a second range. The first range is the entirety of the second photoelectric conversion unit. The first dimension is a dimension of the first range in a direction parallel to a main surface of the second substrate. The second range is a range in which the second light is incident in the second semiconductor layer. The second dimension is a dimension of the second range in the direction parallel to the main surface of the second substrate.

According to a second aspect of the present invention, a solid-state imaging device comprises a first substrate and a second substrate. The first substrate has a plurality of first photoelectric conversion units into which first light is incident. The plurality of first photoelectric conversion units converts the first light into a signal. The second substrate has a plurality of second photoelectric conversion units into which second light is incident. The plurality of second photoelectric conversion units converts the second light into a signal. The second light is the first light transmitted through the plurality of first photoelectric conversion units. The first substrate or the second substrate further has a light blocking layer through which a plurality of opening portions is formed. The light blocking layer reflects a part of the second light transmitted through the first photoelectric conversion unit. The second light from which the light reflected by the light blocking layer is excluded passes through the plurality of opening portions. The second light passing through the plurality of opening portions is incident into the plurality of second photoelectric conversion units. A first dimension of a first range is smaller than a second dimension of a second range. The first range is a range in which the second light is incident into the second photoelectric conversion units. The first dimension is a dimension of the first range in a direction parallel to a main surface of the second substrate. The second range is the entirety of the second photoelectric conversion unit. The second dimension is a dimension of the second range in the direction parallel to the main surface of the second substrate.

According to a third aspect of the present invention, in the first aspect or the second aspect, in a case where the first range and the second range are viewed in a direction perpendicular to the main surface of the second substrate, the first range may be within the second range.

According to a fourth aspect of the present invention, in the second aspect, the second substrate may have the light blocking layer. In a case where the plurality of second photoelectric conversion units and the plurality of opening portions are viewed in a direction perpendicular to the main surface of the second substrate, a center of an area, in which each of the plurality of second photoelectric conversion units overlaps with each of the plurality of opening portions, may substantially coincide with a center of each of the plurality of second photoelectric conversion units.

According to a fifth aspect of the present invention, in the second aspect, the first substrate may have the light blocking layer. In a case where the plurality of first photoelectric conversion units and the plurality of opening portions are viewed in a direction perpendicular to the main surface of the first substrate, a center of an area, in which each of the plurality of first photoelectric conversion units overlaps with each of the plurality of opening portions, may substantially coincide with a center of each of the plurality of first photoelectric conversion units.

According to a sixth aspect of the present invention, in the second aspect, the second substrate may be a front-side illumination type imaging element. The second substrate may have a second semiconductor layer and a second wiring layer. The second semiconductor layer may have the plurality of second photoelectric conversion units. The second wiring layer may include the light blocking layer.

According to a seventh aspect of the present invention, in the second aspect, the first substrate may be a backside illumination type imaging element. The first substrate may have a first semiconductor layer and a first wiring layer. The first semiconductor layer may have the plurality of first photoelectric conversion units.

According to an eighth aspect of the present invention, the imaging apparatus comprises the solid-state imaging device.

### BRIEF DESCRIPTION OF THE DRAWINGS

FIG. 1 is a cross-sectional view of a solid-state imaging device according to a first embodiment of the present invention.

FIG. 2 is a plan view of a first substrate in the solid-state imaging device according to the first embodiment of the present invention.

FIG. 3 is a plan view of a second substrate in the solid-state imaging device according to the first embodiment of the present invention.

FIG. 4 is a cross-sectional view of a solid-state imaging device according to a second embodiment of the present invention.

FIG. 5 is a plan view of a second substrate in the solid-state imaging device according to the second embodiment of the present invention.

FIG. 6 is a cross-sectional view of a solid-state imaging device according to a third embodiment of the present invention.

FIG. 7 is a plan view of a first substrate in the solid-state imaging device according to the third embodiment of the present invention.

FIG. 8 is a block diagram showing a configuration of an imaging apparatus according to a fourth embodiment of the present invention.

FIG. 9 is a cross-sectional view of a conventional solid-state imaging device.

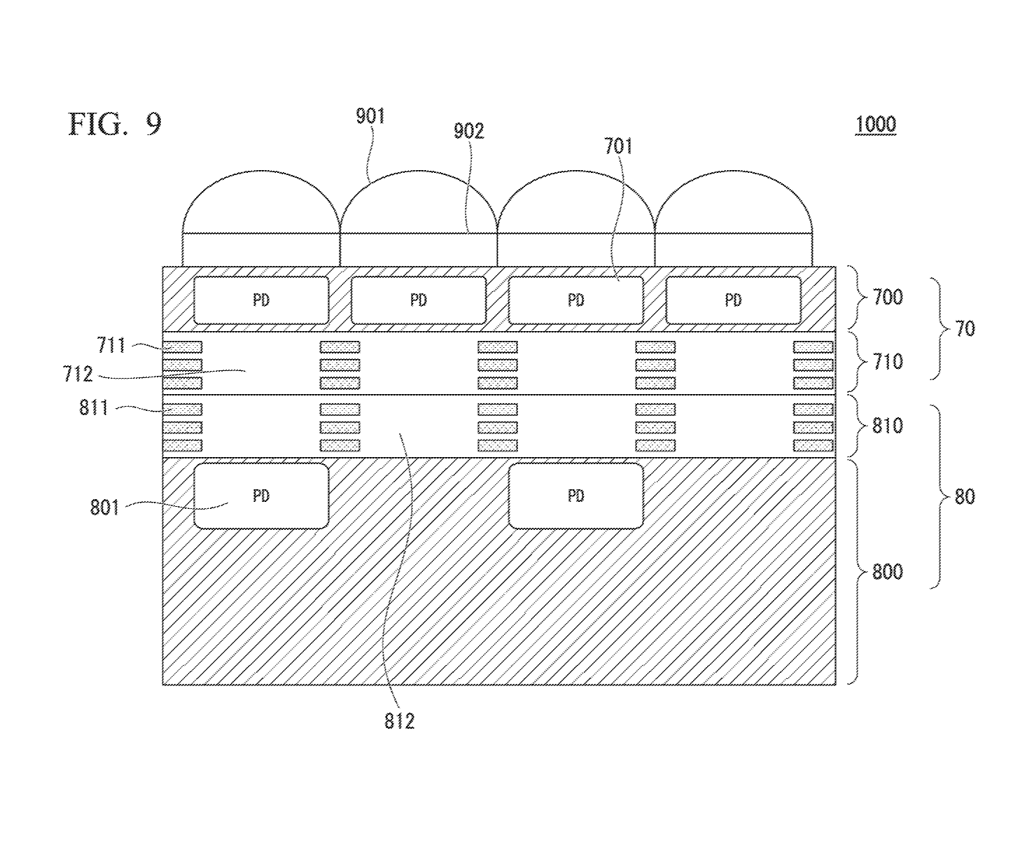

FIG. 10 is a cross-sectional view of a conventional solid-state imaging device.

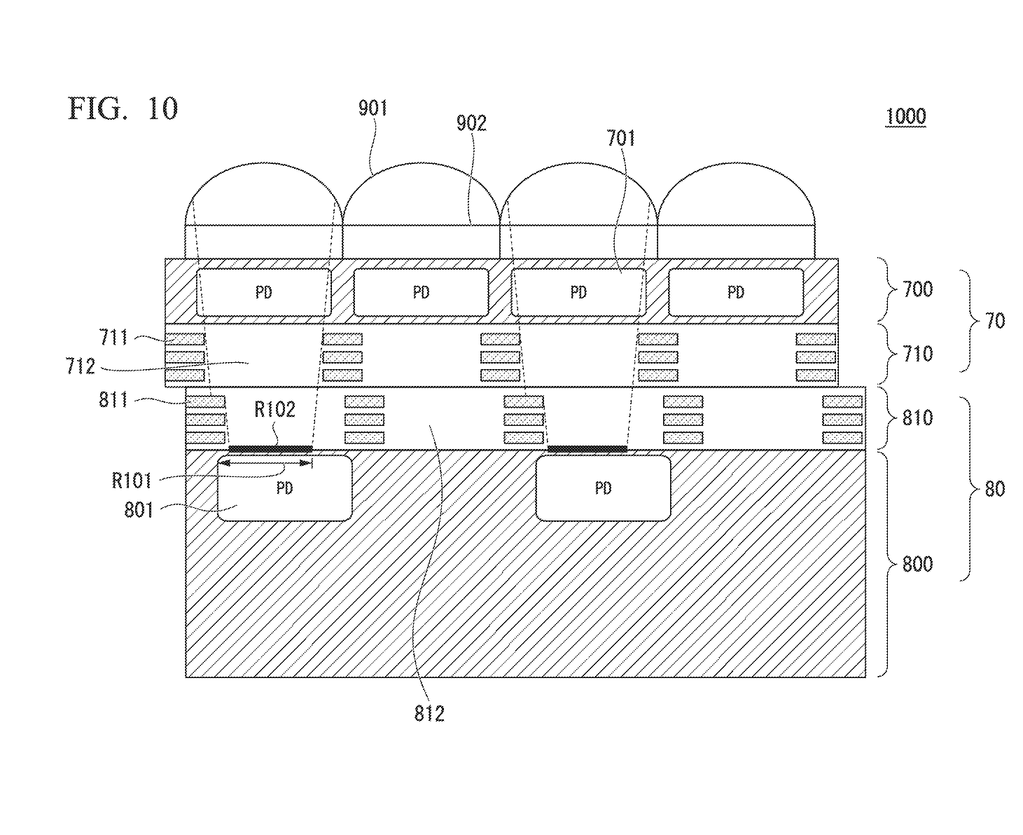

### DETAILED DESCRIPTION OF THE INVENTION

Embodiments of the present invention win be described with reference to the drawings.

### First Embodiment

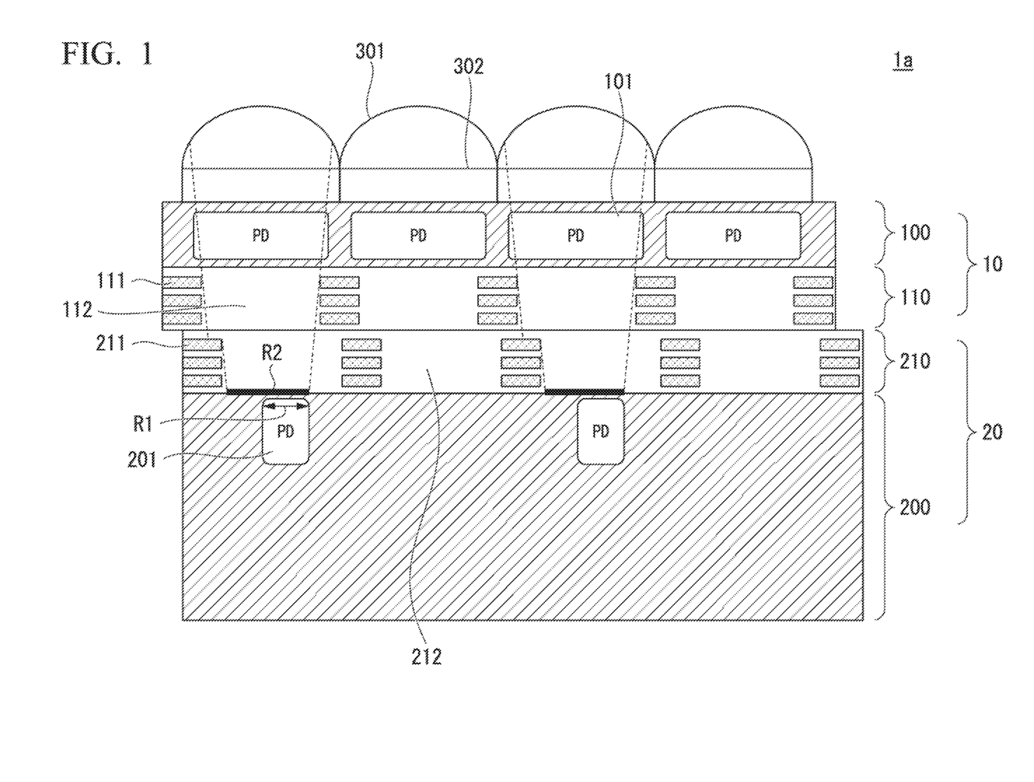

FIG. 1 shows a configuration of a solid-state imaging device 1a according to a first embodiment of the present invention. In FIG. 1, a cross section of the solid-state imaging device 1a is shown. As shown in FIG. 1, the solid-state imaging device 1a has a first substrate 10, a second substrate 20, microlenses 301, and color filters 302. The first substrate 10 and the second substrate 20 are laminated.

The dimensions of portions constituting the solid-state imaging device 1a are not based on dimensions thereof shown in FIG. 1. The dimensions of the portions constituting the solid-state imaging device 1a may be arbitrarily set. In the present specification, dimensions in a specific direction in a specific region are described. In a case where the dimensions of the two specific regions are compared, the dimensions to be compared may be the largest dimensions in the specific direction.

The color filters 302 are disposed on a main surface (the largest surface among the plurality of surfaces constituting a surface of the substrate) of the first substrate 10, and the microlenses 301 are disposed on the color filters 302. Although there is a plurality of microlenses 301 in FIG. 1, the reference sign of one microlens 301 is shown as a representative thereof. Further, although there is a plurality of color filters 302 in FIG. 1, the reference sign of one color filter 302 is shown as a representative thereof.

Light, which is emitted from a subject and is transmitted through an imaging lens disposed on an optically front side of the solid-state imaging device 1a, is incident into the microlenses 301. The microlenses 301 firm an image of the light transmitted through the imaging lens. The color filters 302 transmit light with wavelengths corresponding to predetermined colors.

The first substrate 10 has a first semiconductor layer 100 and a first wiring layer 110. The first semiconductor layer 100 and the first wiring layer 110 are superposed in a direction (for example, a direction substantially perpendicular to the main surface) crossing the main surface of the first substrate 10 (the largest surface among a plurality of surfaces constituting surfaces of the substrate). Further, the first semiconductor layer 100 and the first wiring layer 110 are in contact with each other.

The first semiconductor layer 100 has first photoelectric conversion units 101. Although there is a plurality of first photoelectric conversion units 101 in FIG. 1, the reference sign of one first photoelectric conversion unit 101 is shown as a representative thereof. The first semiconductor layer 100 is made of a material including a semiconductor such as silicon (Si). For example, the first photoelectric conversion units 101 are made of a semiconductor material having an impurity concentration different from that of the semiconductor material forming the first semiconductor layer 100. The first semiconductor layer 100 has a first surface in contact with the first wiring layer 110. The second surface opposite to the first surface of the first semiconductor layer 100 is in contact with the color filters 302. The second surface of the first semiconductor layer 100 constitutes one of the main surfaces of the first substrate 10.

The light transmitted through the microlenses 301 and the color filters 302 is incident onto the first semiconductor layer 100. The light incident onto the first semiconductor layer 100 travels through the first semiconductor layer 100, and is incident into the first photoelectric conversion units 101. The first photoelectric conversion units 101 convert the incident light into a signal.

A first wiring layer 110 includes first wires 111 and a first interlayer insulation film 112. Although there is a plurality of first wires 111 in FIG. 1, the reference sign of one first wire 111 is shown as a representative thereof.

The first wires 111 are made of a material (for example, a metal such as aluminum (Al) or copper (Cu)) which has conductivity. The first wiring layer 110 has a first surface and a second surface. The first surface of the first wiring layer 110 is in contact with the second substrate 20. The second surface opposite to the first surface of the first wiring layer 110 is in contact with the first semiconductor layer 100. The first surface of the first wiring layer 110 constitutes one of the main surfaces of the first substrate 10.

The first wires 111 are a thin film on which a wiring pattern is formed. The first wires 111 transmit the signals generated by the first photoelectric conversion units 101 and other signals (a power supply voltage, a ground voltage, and the like). Only one layer of the first wires 111 may be formed, and a plurality of layers of the first wires 111 may be thrilled. In the example shown in FIG. 1, three layers of the first wires 111 are formed. The plurality of layers of the first wires 111 is connected by vias not shown in the drawings.

In the first wiring layer 110, a part other than the first wires 111 is formed of a first interlayer insulation film 112 formed of silicon dioxide (SiO₂) or the like.

The second substrate 20 has a second semiconductor layer 200 and a second wiring layer 210. The second semiconductor layer 200 and the second wiring layer 210 are superposed in a direction (for example, a direction substantially perpendicular to the main surface) crossing the main surface of the second substrate 20. Further, the second semiconductor layer 200 and the second wiring layer 210 are in contact with each other.

The second semiconductor layer 200 has second photoelectric conversion units 201. Although there is a plurality of second photoelectric conversion units 201 in FIG. 1, the reference sign of one second photoelectric conversion unit 201 is shown as a representative thereof. The second semiconductor layer 200 is made of a material including a semiconductor such as silicon (Si). For example, the second photoelectric conversion units 201 are made of a semiconductor material having an impurity concentration different from that of the semiconductor material forming the second semiconductor layer 200. The second photoelectric conversion units 201 are formed in regions corresponding to the first photoelectric conversion units 101. That is, each second photoelectric conversion unit 201 is formed at a position where light transmitted through each first photoelectric conversion unit 101 is incident. The second semiconductor layer 200 has a first surface and a second surface. The first surface of the second semiconductor layer 200 is in contact with the second wiring layer 210. The second surface of the second semiconductor layer 200 constitutes one of the main surfaces of the second substrate 20. The second photoelectric conversion units 201 are formed in the vicinity of the first surface onto which light is incident in the second semiconductor layer 200.

Light transmitted through the first photoelectric conversion units 101 passes through the first wiring layer 110, and is incident onto the second wiring layer 210 of the second substrate 20. The light incident onto the second wiring layer 210 passes through the second wiring layer 210, and is incident onto the second semiconductor layer 200. The light incident onto the second semiconductor layer 200 travels through the second semiconductor layer 200, and is incident onto the second photoelectric conversion units 201. The second photoelectric conversion units 201 convert the incident light into a signal.

The second wiring layer 210 includes second wires 211 and a second interlayer insulation film 212. Although there is a plurality of second wires 211 in FIG. 1, the reference sign of one second wire 211 is shown as a representative thereof.

The second wires 211 are made of a material (for example, a metal such as aluminum (Al) or copper (Cu)) having conductivity. The second wiring layer 210 has a first surface and a second surface. The first surface of the second wiring layer 210 is in contact with the first wiring layer 110. The second surface opposite to the first surface of the second wiring layer 210 is in contact with the second semiconductor layer 200. The first surface of the second wiring layer 210 constitutes one of the main surfaces of the second substrate 20.

The second wires 211 are a thin film on which a wiring pattern is formed. The second wires 211 transmit the signals generated by the second photoelectric conversion units 201 and other signals (a power supply voltage, a ground voltage, and the like). Only one layer of the second wires 211 may be formed, and a plurality of layers of the second wires 211 may be formed. In the example shown in FIG. 1, three layers of the second wires 211 are formed. The plurality of layers of the second wires 211 is connected by vias not shown in the drawings.

In the second wiring layer 210, a part other than the second wires 211 is formed of the second interlayer insulation film 212 formed of silicon dioxide (SiO₂) or the like.

The first substrate 10 and the second substrate 20 are laminated in a state where the first wiring layer 110 of the first substrate 10 and the second wiring layer 210 of the second substrate 20 face each other. The first substrate 10 and the second substrate 20 are electrically connected.

The solid-state imaging device la has the following, characteristics. The first substrate 10 has the plurality of first photoelectric conversion units 101 into which first light is incident. The plurality of first photoelectric conversion units 101 converts the first light into a signal. The second substrate 20 has the second semiconductor layer 200 onto which second light is incident. The second semiconductor layer 200 includes the plurality of second photoelectric conversion units 201 into which the second light incident onto the second semiconductor layer 200 is incident. The plurality of second photoelectric conversion units 201 converts the second light into a signal. The second light is the first light transmitted through the plurality of first photoelectric conversion units 101.

A first dimension of a first range R1 is smaller than a second dimension of a second range R2. The first range R1 is the entirety of the second photoelectric conversion unit 201. The first dimension is a dimension (maximum dimension) of the first range R1 in a direction parallel to the main surface of the second substrate 20. A second range R2 is a range in which the second light is incident in the second semiconductor layer 200. The second dimension is a dimension (maximum dimension) of the second range K2 in the direction parallel to the main surface of the second substrate 20. In a case where the first range R1 and the second range R2 are viewed in a direction perpendicular to the main surface of the second substrate 20, it is preamble that the first range R1 is within the second range R2. Although there is a plurality of first ranges R1 in FIG. 1, the reference sign of one first range R1 is shown as a representative thereof. Further, although there is a plurality of second ranges R2 in FIG. 1, the reference sign of one second range R2 is shown as a representative thereof.

The solid-state imaging device la has a plurality of microlenses 301 onto which first light is incident. The first light transmitted through the plurality of microlenses 301 is incident into the plurality of first photoelectric conversion units 101.

The dimension of the second range R2 of the second semiconductor layer 200 can be calculated by a shape of the microlens 301, refractive indexes and transmittances of the color filter 302 and the first semiconductor layer 100, a distance from the microlens 301 to the second range R2, and the like. Further, optical simulation using the ray tracing method or the finite-difference time-domain (FDTD) method is used for the calculation. The FDTD method is a method of electromagnetic field analysis. The first dimension of the first range R1 of the second photoelectric conversion unit 201 is the dimension of the second photoelectric conversion unit 201 in the direction parallel to the main surface of the second substrate 20. That is, the second light can be incident in the entire area of the second photoelectric conversion unit 201. The first dimension is smaller than the dimension of the first photoelectric conversion unit 101. The dimension of the first photoelectric conversion unit 101 is the dimension of the first photoelectric conversion unit 101 in the direction parallel to the main surface of the first substrate 10.

In a case where there is no positional deviation between the first substrate 10 and the second substrate 20, the following condition is satisfied. In a case where the plurality of first photoelectric conversion units 101 and the plurality of second photoelectric conversion units 201 are viewed in the direction perpendicular to the main surface of the first substrate 10 or the second substrate 20, the respective centers of the plurality of the first photoelectric conversion units 101 substantially coincide with the respective centers of the plurality of second photoelectric conversion units 201. Further, in a case where the plurality of second photoelectric conversion units 201 and the plurality of second ranges R2 are viewed in the direction perpendicular to the main surface of the second substrate 20, the respective centers of the plurality of second photoelectric conversion units 201 substantially coincide with the respective centers of the plurality of second ranges R2.

The first substrate 10 or second substrate 20 has wires, that is, the first wires 111 or the second wires 211. In a case where there is no positional deviation between the first substrate 10 and the second substrate 20, the first wires 111 and the second wires 211 are positioned so as not to obstruct travel of the second light transmitted through the first photoelectric conversion unit 101. In FIG. 1, there is positional deviation between the first substrate 10 and the second substrate 20. In FIG. 1, the second substrate 20 deviates to the right with respect to the first substrate 10. In FIG. 1, in a case where the plurality of first photoelectric conversion units 101 and the plurality of second photoelectric conversion units 201 are viewed in the direction perpendicular to the main surface of the first substrate 10 or the second substrate 20, the respective centers of the plurality of the first photoelectric. conversion units 101 do not coincide with the respective centers of the plurality of second photoelectric conversion units 201. Further, in FIG. 1, in a case where the plurality of second photoelectric conversion units 201 and the plurality of second ranges R2 are viewed in the direction perpendicular to the main surface of the second substrate 20, the respective centers of the plurality of second photoelectric conversion units 201 do not coincide with the respective centers of the plurality of second ranges R2.

The first range R1 of the second photoelectric conversion unit 201 is smaller than the second range R2 of the second semiconductor layer 200. Therefore, in a case where there is positional deviation between the first substrate 10 and the second substrate 20, when the first range R1 and the second range R2 are viewed in the direction perpendicular to the main surface of the second substrate 20, the first range R1 is likely to be included in the second range R2. Consequently, the amount of light incident into the second photoelectric conversion unit 201 is unlikely to depend on the amount of the positional deviation between the first substrate 10 and the second substrate 20.

In a case where there is small positional deviation between the first substrate 10 and the second substrate 20, most of the second light transmitted through the first photoelectric conversion units 101 is incident onto the second photoelectric conversion units 201. However, as shown in FIG. 1, in a case where there is large positional deviation between the first substrate 10 and the second substrate 20, the second wires 211 overlap with the optical path of the second light transmitted through the first photoelectric conversion units 101. Hence, a part of the second light is blocked by the second wires 211. The first range R1 of the second photoelectric conversion unit 201 is smaller than a third dimension of the second range R2 of the second semiconductor layer 200. Therefore, the amount of the second light incident on the second photoelectric conversion units 201 is unlikely to depend on the amount of the second light blocked by the second wires 211.

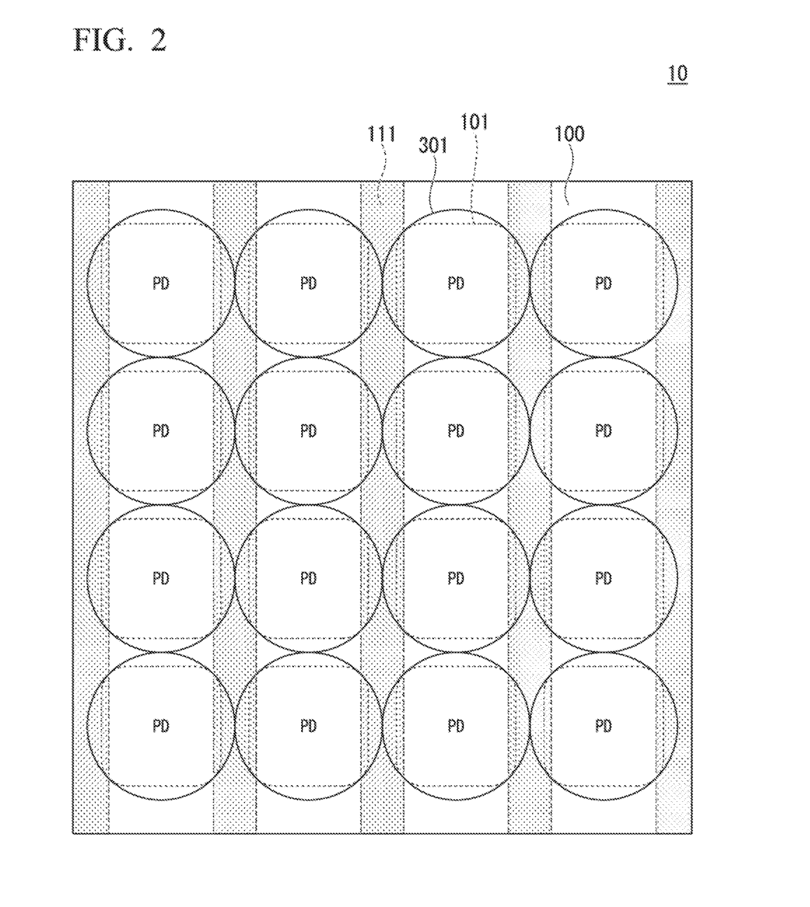

FIG. 2 shows arrangement of the plurality of first photoelectric conversion units 101. In FIG. 2, the first substrate 10 viewed in the direction perpendicular to the main surface of the first substrate 10 is shown. In FIG. 2, the surface of the first semiconductor layer 100 is shown. As shown in FIG. 2, the first substrate 10 has the plurality of first photoelectric conversion units 101 and the plurality of microlenses 301. In FIG. 2, the reference signs of one first photoelectric conversion unit 101 and one microlens 301 are shown as representatives thereof. The plurality of first photoelectric conversion units 101 is arranged in a matrix. In addition, the plurality of microlenses 301 is arranged in a matrix. Further, in FIG. 2, the positions of the first wires 111 are shown.

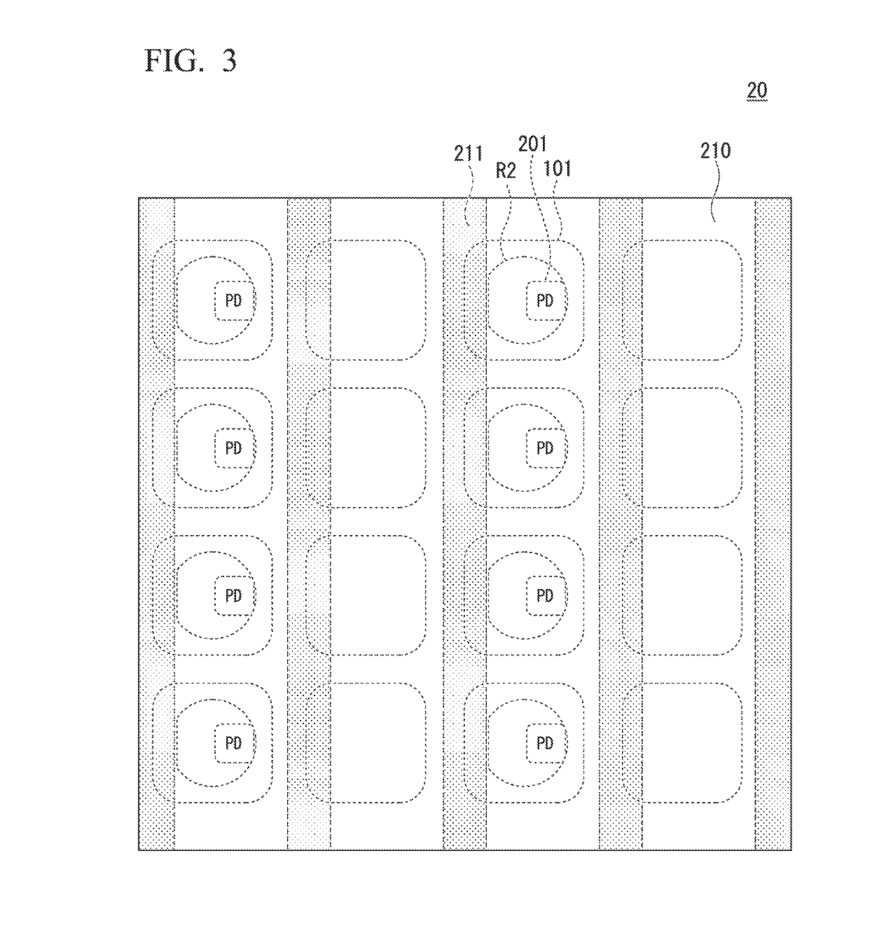

FIG. 3 shows arrangement of the plurality of second photoelectric conversion units 201. In FIG. 3, the second substrate 20 viewed in the direction perpendicular to the main surface of the second substrate 20 is shown. In FIG. 3, the surface of the second wiring Fiver 210 is shown. As shown in FIG. 3, the second substrate 20 has the plurality of second photoelectric conversion units 201 and the plurality of second wires 211. In FIG. 3, the reference signs of one second photoelectric conversion unit 201 and one second wire 211 are shown as representatives thereof. The plurality of second photoelectric conversion units 201 is arranged in a matrix. Further, in FIG. 3, the positions of the first photoelectric conversion units 101 and the second ranges R2 of the second semiconductor layer 200 are shown.

There is positional deviation between the first substrate 10 and the second substrate 20. Therefore, as shown in FIG. 3, each second photoelectric conversion unit 201 deviates to the right with respect to each first photoelectric conversion unit 101. Further, each second photoelectric conversion unit 201 deviates to the right with respect to each second range R2. However, the second photoelectric conversion unit 201 is within the second range R2. In a case where the positional deviation between the first substrate 10 and the second substrate 20 is small, the second photoelectric conversion unit 201 is within the second range R2, regardless of the amount of the deviation. Therefore, the amount of the second light incident into the second photoelectric conversion units 201 is unlikely to depend on the amount of the positional deviation between the first substrate 10 and the second substrate 20.

As shown in FIGS. 2 and 3, the first photoelectric conversion units 101 and the second photoelectric conversion units 201 have rectangular shapes. Further, the second range R2 has a shape in which a part of the circle is missing. Shapes of the first photoelectric conversion units 101, the second photoelectric conversion units 201, and the second ranges R2 are not limited to the shapes shown in FIGS. 2 and 3. Depending on these shapes and the amount of deviation, there is a possibility that a part of the first range R1 of the second photoelectric conversion unit 201 is not included in the second range R2. However, the amount of reduction of the light incident into the first range R1 is small.

For example, the second dimension (the diameter of the circular portion) of the second range R2 is R. For example, the amount of positional deviation between the first substrate 10 and the second substrate 20 is D. In a case where the first dimension of the first range R1 is smaller than R-2D, when the first range R1 and the second range R2 are viewed in the direction perpendicular to the main surface of the second substrate 20, the first range R1 is likely to be included in the second range R2.

The first dimension of the first range R1 of the second photoelectric conversion unit 201 is greater than 0. For example, at the time of designing the solid-state imaging device 1a, the first dimension of the first range R1 is determined to be greater than or equal to R-2Dmax. Dmax is a maximum value of the allowable amount of the positional deviation between the first substrate 10 and the second substrate 20. For example, in a case where the first substrate 10 and the second substrate 20 are electrically connected by bumps. Dmax may be equal to a dimension of each bump. Alternatively, Dmax may be a value obtained from the measurement result of the amount of the positional deviation between the first substrate 10 and the second substrate 20.

The solid-state imaging device of each aspect of the present invention may exclude a configuration corresponding to at least one of the first wiring layer 110, the second wiring layer 210, the microlenses 301, and the color filters 302.

According to the first embodiment, the solid-state imaging device 1a having the first substrate 10 and the second substrate 20 is formed.

In the first embodiment, the, amount of light incident into the second photoelectric conversion units 201 is unlikely to depend on the amount of the positional deviation between the first substrate 10 and the second substrate 20. As a result, it is possible to reduce variations in signals due to the positional deviation between the first substrate 10 and the second substrate 20.

### Second Embodiment

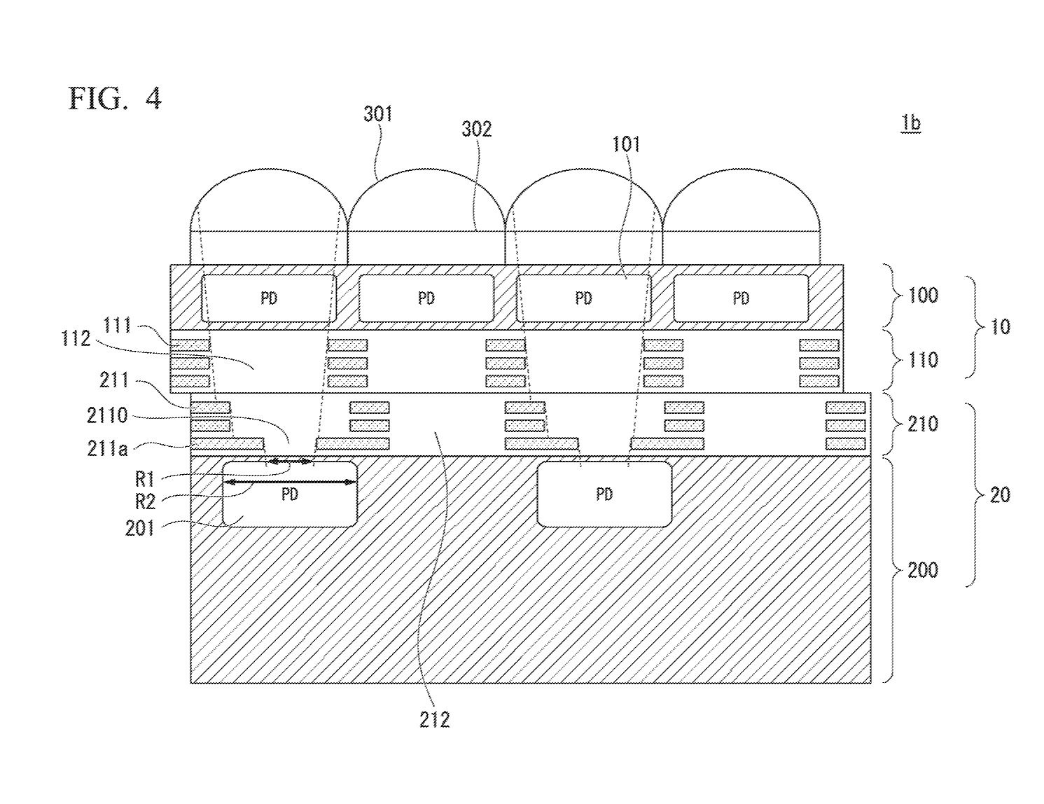

FIG. 4 shows a configuration of a solid-state imaging device 1b according to a second embodiment of the present invention. In FIG. 4, a cross section of the solid-state imaging device 1b is shown. As shown in FIG. 4, the solid-state imaging device 1b has a first substrate 10, a second substrate 20, microlenses 301, and color filters 302. The first substrate 10 and the second substrate 20 are laminated.

The configuration shown in FIG. 4 will be described centering on different points with the configuration shown in FIG. 1.

The second substrate 20 has a light blocking layer 211a in which a plurality of opening portions 2110 is formed. In FIG. 4, the reference sign of one opening portion 2110 is shown as a representative thereof. The light blocking layer 211a is positioned to obstruct travel of the second light transmitted through the first photoelectric conversion units 101. The light blocking layer 211a reflects a part of the second light transmitted through the first photoelectric conversion units 101. The second light other than the light reflected by the light blocking layer 211a passes through the plurality of opening portions 2110. The second light having passed through the plurality of opening portions 2110 is incident into the plurality of second photoelectric conversion units 201.

A first dimension of a first range R1 is smaller than a second dimension of a second range R2. The first range R1 is a range in which the second light is incident into the second photoelectric conversion unit 201. The first dimension is a dimension (maximum dimension) of the first range R1 in a direction parallel to the main surface of the second substrate 20. The second range R2 is the entirety of the second photoelectric conversion unit 201. The second dimension is a dimension (maximum dimension of the second range R2 in the direction parallel to the main surface of the second substrate 20. In a case where the first range R1 and the second range R2 are viewed in a direction perpendicular to the main surface of the second substrate 20, it is preferable that the first range R1 is within the second range R2. Although there is a plurality of first ranges R1 in FIG. 4, the reference sign of one first range R1 is shown as a representative thereof. Further, although there is a plurality of second ranges R2 in FIG. 4, the reference sign of one second range R2 is shown as a representative thereof.

In a case where the plurality of second photoelectric conversion units 201 and the plurality of opening portions 2110 are viewed in the direction perpendicular to the main surface of the second substrate 20, a center of an area, in which each of the plurality of second photoelectric conversion units 201 overlaps with each of the plurality of opening portions 2110, substantially coincides with a center of each of the plurality of second photoelectric conversion units 201.

The first substrate 10 is a backside illumination (BSI) type imaging element. The first substrate 10 has a first semiconductor layer 100 and a first wiring layer 110. The first semiconductor layer 100 has a plurality of first photoelectric conversion units 101. The second substrate 20 is a front-side illumination (FSI) type imaging element. The second substrate 20 has a second semiconductor layer 200 and a second wiring layer 210. The second semiconductor layer 200 has a plurality of second photoelectric conversion units 201. The second wiring layer 210 includes a light blocking layer 211a.

In FIG. 4, the light blocking layer 211a is a single layer of the second wires 211. In FIG. 4, the light blocking layer 211a is the layer of the second wires 211 closest to the second photoelectric conversion units 201. The light blocking layer 211a may have a structure different from that of the second wires 211.

The first dimension of the first range R1 of the second photoelectric conversion unit 201 is smaller than the dimension of the opening portion 2110. The dimension of the opening portion 2110 is a dimension of the opening portion 2110 in the direction parallel to the main surface of the second substrate 20.

The second dimension of the second range R2 of the second photoelectric conversion unit 201 is approximately equal to the dimension of the first photoelectric conversion unit 101 in the direction parallel to the main surface of the first substrate 10. The second dimension is greater than the dimension of the opening portion 2110.

Regarding points other than the above points, the configuration shown in FIG. 4 is the same as the configuration shown in FIG. 1.

The first range R1 of the second photoelectric conversion unit 201 is smaller than the second range R2 of the second photoelectric conversion unit 201. Therefore, in a case where there is positional deviation between the first substrate 10 and the second substrate 20, when the first range R1 and the second range R2 are viewed in the direction perpendicular to the main surface of the second substrate 20, the first range R1 is likely to be included in the second range R2. Consequently, the amount of light incident into the second photoelectric conversion unit 201 is unlikely to depend on the amount of the positional deviation between the first substrate 10 and the second substrate 20.

The arrangement of the plurality of first photoelectric conversion units 101 is the same as the arrangement shown in FIG. 2.

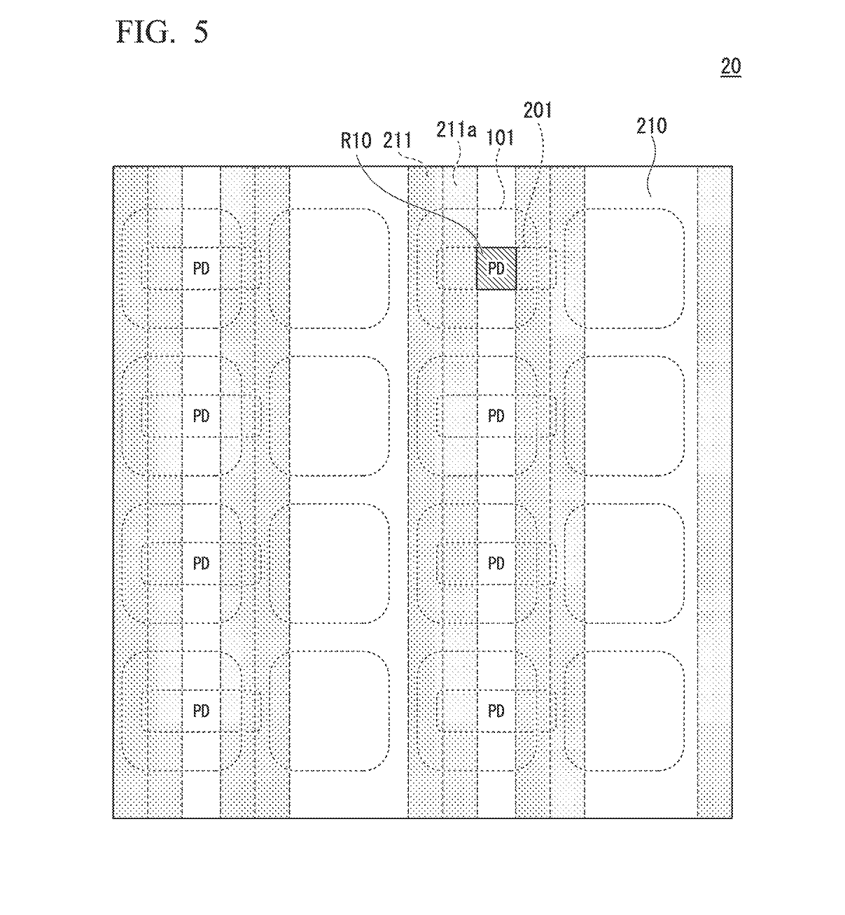

FIG. 5 shows arrangement of the plurality of second photoelectric conversion units 201. In FIG. 5, the second substrate 20 viewed in the direction perpendicular to the main surface of the second substrate 20 is shown. In FIG. 5, the surface of the second wiring layer 210 is shown. As shown in FIG. 5, the second substrate 20 has a plurality of second photoelectric conversion units 201, a plurality of second wires 211, and a plurality of light blocking lavers 211a. In FIG. 5, the reference signs of one second photoelectric conversion unit 201, one second wire 211, and one light blocking layer 211a are shown as representatives thereof. The plurality of second photoelectric. conversion units 201 is arranged in a matrix. Further, in FIG. 5, the positions of the first photoelectric conversion units 101 are shown.

A center of a region R10, in which each of the plurality of second photoelectric conversion units 201 overlaps with each of the plurality of opening, portions 2110, substantially coincides with a center of each of the plurality of second photoelectric conversion units 201. In FIG. 5, the reference sign of one region R10 is shown as a representative thereof.

There is positional deviation between the first substrate 10 and the second substrate 20. Therefore, as shown in FIG. 5, each second photoelectric conversion unit 201 deviates to the right with respect to each first photoelectric conversion unit 101. However, the region R10, in which the opening portion 2110 of the light blocking layer 211a overlaps with the second photoelectric conversion unit 201, is inside the first photoelectric conversion unit 101. In a case where the positional deviation between the first substrate 10 and the second substrate 20 is small, the region R10 is inside the first photoelectric conversion unit 101, regardless of the amount of the deviation. Therefore, the amount of the second light incident into the second photoelectric conversion unit 201 is unlikely to depend on the amount of the positional deviation between the first substrate 10 and the second substrate 20.

In a case where the second photoelectric conversion unit 201 is viewed in the direction perpendicular to the main surface of the second substrate 20, it is preferable that the first range R1 of the second photoelectric conversion unit 201 is included in a third range equivalent to the second range R2 of the second semiconductor layer 200 in the first embodiment. For example, the second dimension (the diameter of the circular portion) of the second range R2 is R. For example, the amount of positional deviation between the first substrate 10 and the second substrate 20 is D. In a case where the first dimension of the first range R1 is smaller than R-2D. when the second photoelectric conversion unit 201 is viewed in the direction perpendicular to the main surface of the second substrate 20, the first range R1 is likely to be included in the second range R2.

The first dimension of the first range R1 of the second photoelectric conversion unit 201 is greater than 0. For example, at the time of designing the solid-state imaging device 1b, the first dimension of the first range R1 is determined to be greater than or equal to R-2Dmax. Dmax is a maximum value of the allowable amount of the positional deviation between the first substrate 10 and the second substrate 20. For example, in a case where the first substrate 10 and the second substrate 20 are electrically connected by bumps. Dmax may be equal to a dimension of each bump. Alternatively, Dmax may bee a value obtained from the measurement result of the amount of the positional deviation between the first substrate 10 and the second substrate 20. The dimensions of the opening portion 2110 are determined such that the first dimension of the first range R1 is set as a determined dimension.

According to the second embodiment, the solid-state imaging device 1b having the first substrate 10 and the second substrate 20 is formed.

In the second embodiment, the amount of light incident into the second photoelectric conversion unit 201 is unlikely to depend on the amount of the positional deviation between the first substrate 10 and the second substrate 20. As a result, it is possible to reduce variations in signals due to the positional deviation between the first substrate 10 and the second substrate 20.

### Third Embodiment

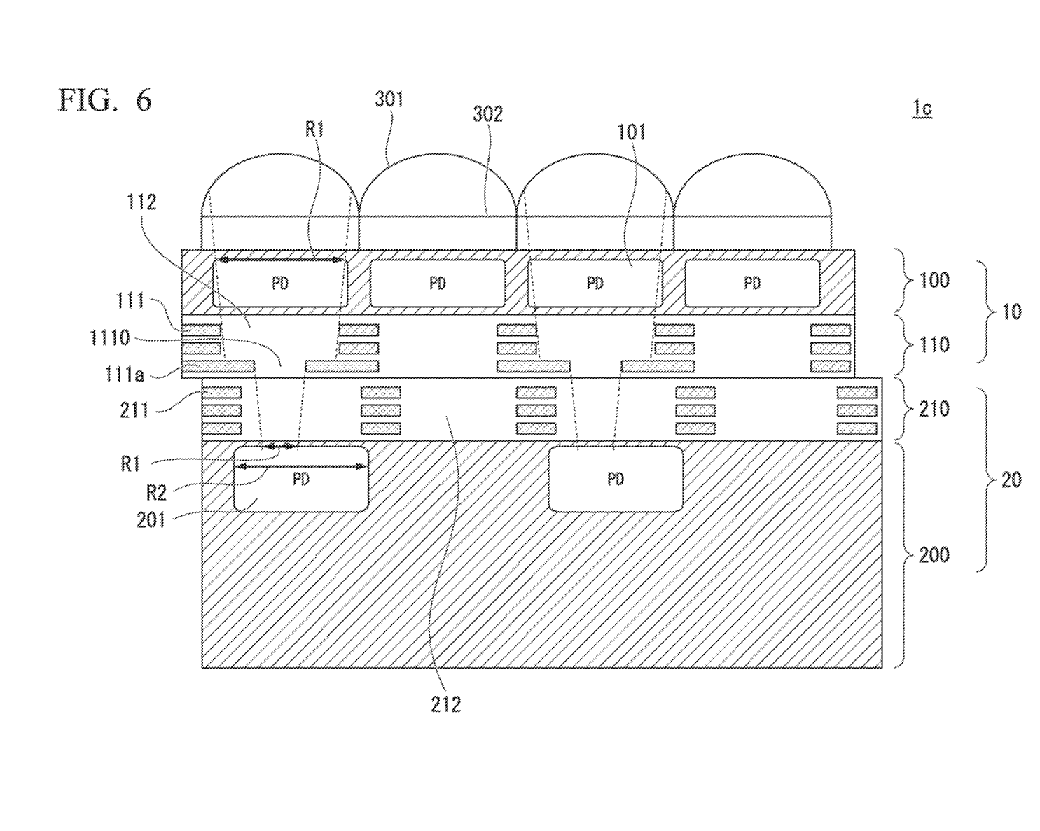

FIG. 6 shows a configuration of a solid-state imaging device 1c according to a third embodiment of the present invention. In FIG. 6, a cross section of the solid-state imaging device 1c is shown. As shown in FIG. 6, the solid-state imaging device 1c has a first substrate 10, a second substrate 20, microlenses 301, and color filters 302. The first substrate 10 and the second substrate 20 are laminated.

The configuration shown in FIG. 6 will be described centering on different points with the configuration shown in FIG. 1.

The first substrate 10 has a light blocking layer 111a. in which a plurality of opening portions 1110 is formed. In FIG. 6, the reference sign of one opening portion 1110 is shown as a representative thereof. The light blocking layer 111a is positioned to obstruct travel of the second light transmitted through the first photoelectric conversion units 101. The light blocking layer 111a reflects a part of the second light transmitted through the first photoelectric conversion units 101. The second light other than the light reflected by the light blocking layer 111a passes through the plurality of opening portions 1110. The second light having passed through the plurality of opening portions 1110 is incident into the plurality of second photoelectric conversion units 201.

A first dimension of a first range R1 is smaller than a second dimension of a second range R2. The first range R1 is a range in which the second light is incident into the second photoelectric conversion unit 201. The first dimension is a dimension (maximum dimension) of the first range R1 in a direction parallel to the main surface of the second substrate 20. The second range R2 is the entirety of the second photoelectric conversion unit 201. The second dimension is a dimension (maximum dimension) of the second range R2 in the direction parallel to the main surface of the second substrate 20. In a case where the first range R1 and the second range R2 are viewed in a direction perpendicular to the main surface of the second substrate 20, it is preferable that the first range R1 is within the second range R2. Although there is a plurality of first ranges R1 in FIG. 6, the reference sign of one first range R1 is shown as a representative thereof. Further, although there is a plurality of second ranges R2 in FIG. 6, the reference sign of one second range R2 is shown as a representative thereof.

In a case where the plurality of first photoelectric conversion units 101 and the plurality of opening portions 1110 are viewed in the direction perpendicular to the main surface of the first substrate 10, a center of an area, in which each of the plurality of first photoelectric conversion units 101 overlaps with each of the plurality of opening portions 1110, substantially coincides with a center of each of the plurality of first photoelectric conversion units 101.

The first substrate 10 is a backside illumination type imaging element. The first substrate 10 has a first semiconductor layer 100 and a first wiring layer 110. The first semiconductor layer 100 has a plurality of first photoelectric conversion units 101. The second substrate 20 is a front-side illumination type imaging element. The second substrate 20 has a second semiconductor layer 200 and a second wiring layer 210. The second semiconductor layer 200 has a plurality of second photoelectric conversion units 201. The first wiring layer 110 includes a light blocking layer 111a.

In FIG. 6, the light blocking layer 111a is a single layer of the first wires 111. In FIG. 6, the light blocking layer 111a. is the layer of the first wires 111 closest to the second photoelectric conversion units 201. The light blocking layer 111a may have a structure different from that of the first wires 111.

The first dimension of the first range R1 of the second photoelectric conversion unit 201 is smaller than the dimension of the opening portion 1110. The dimension of the opening portion 1110 is a dimension of the opening portion 1110 in the direction parallel to the main surface of the first substrate 10.

The second dimension of the second range R2 of the second photoelectric conversion unit 201 is approximately equal to the dimension of the first photoelectric conversion unit 101 in the direction parallel to the main surface of the first substrate 10. The second dimension is greater than the dimension of the opening portion 1110.

Regarding points other than the above points, the configuration shown in FIG. 6 is the same as the configuration shown in FIG. 1.

The first range R1 of the second photoelectric conversion unit 201 is smaller than the second range R2 of the second photoelectric conversion unit 201. Therefore, in a case where there is positional deviation between the first substrate 10 and the second substrate 20, when the first range R1 and the second range R2 are viewed in the direction perpendicular to the main surface of the second substrate 20, the first range R1 is likely to be included in the second range R2. Consequently, the amount of light incident into the second photoelectric conversion unit 201 is unlikely to depend on the amount of the positional deviation between the first substrate 10 and the second substrate 20.

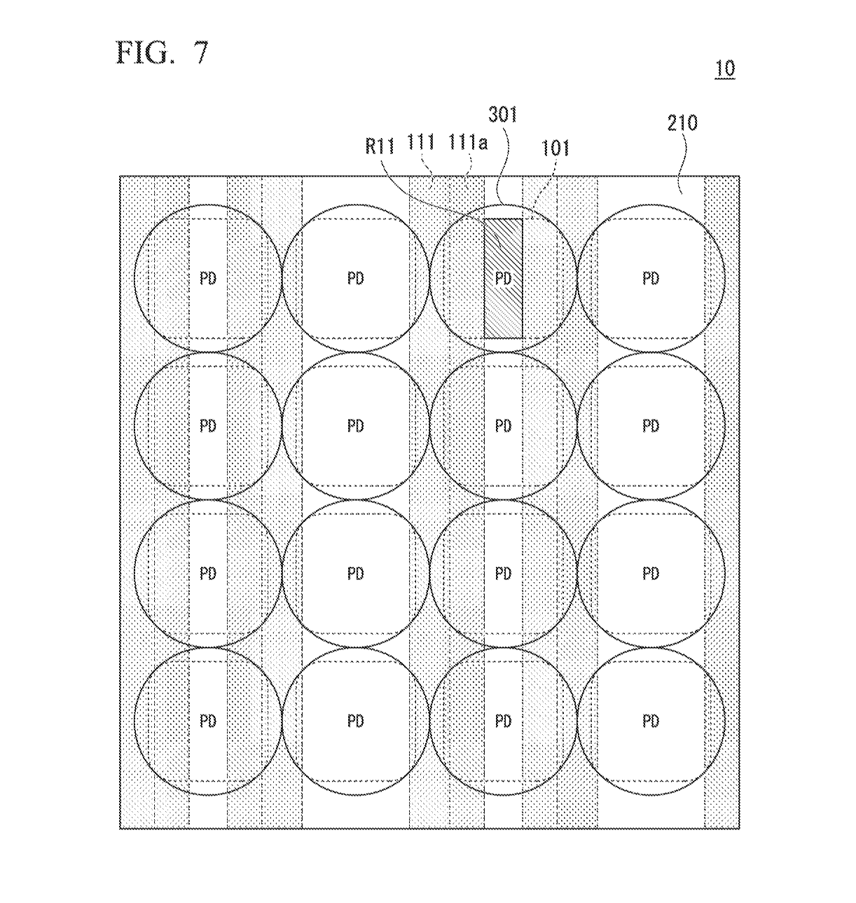

FIG. shows arrangement of the plurality of first photoelectric conversion units 101. In FIG. 7, the first substrate 10 viewed in the direction perpendicular to the main surface of the first substrate 10 is shown. In FIG. 7, the surface of the first semiconductor layer 100 is shown. As shown in FIG. 7, the first substrate 10 has the plurality of first photoelectric conversion units 101 and the plurality of microlenses 301. In FIG. 7, the reference signs of one first photoelectric conversion unit 101 and one microlens 301 are shown as representatives thereof. The plurality of first photoelectric conversion units 101 is arranged in a matrix. In addition, the plurality of microlenses 301 is arranged in a matrix. Further, in FIG. 7, the positions of the first wires 111 and the light blocking layer 111a are shown.

A center of a region R11, in which each of the plurality of first photoelectric conversion units 101 overlaps with each of the plurality of opening portions 1110, substantially coincides with a center of each of the plurality of first photoelectric conversion units 101. In FIG. 7, the reference sign of one region R11 is shown as a representative thereof.

The arrangement of the plurality of second photoelectric conversion units 201 is the same as the arrangement shown in FIG. 5. In the third embodiment, there is no light blocking layer 211a.

For example, the second dimension of the second photoelectric conversion unit 201 is L. For example, the amount of positional deviation between the first substrate 10 and the second substrate 20 is D. In a case where the first dimension of the first range R1 is smaller than L-2D, when the second photoelectric conversion unit 201 is viewed in the direction perpendicular to the main surface of the second substrate 20, the dimension of the first range R1 is likely to be constant, regardless of the amount of deviation.

The first dimension of the first range R1 of the second photoelectric conversion unit 201 is greater than 0. For example, at the time of designing the solid-state imaging device 1c, the first dimension of the first range R1 is determined to be greater than or equal to L-2Dmax. Dmax is a maximum value of the allowable amount of the positional deviation between the first substrate 10 and the second substrate 20. For example, in a case where the first substrate 10 and the second substrate 20 are electrically connected by bumps. Dmax may be equal to a dimension of each bump. Alternatively, Dmax may be a value obtained from the measurement result of the amount of the positional deviation between the first substrate 10 and the second substrate 20. The dimensions of the opening portion 1110 are determined such that the first dimension of the first range R1 is set as a determined dimension.

According to the third embodiment, the solid-state imaging device 1c having the first substrate 10 and the second substrate 20 is formed.

In the third embodiment, the amount of light incident into the second photoelectric conversion unit 201 is unlikely to depend on the amount of the positional deviation between the first substrate 10 and the second substrate 20. As a result, it is possible to reduce variations in signals due to the positional deviation between the first substrate 10 and the second substrate 20.

### Fourth Embodiment

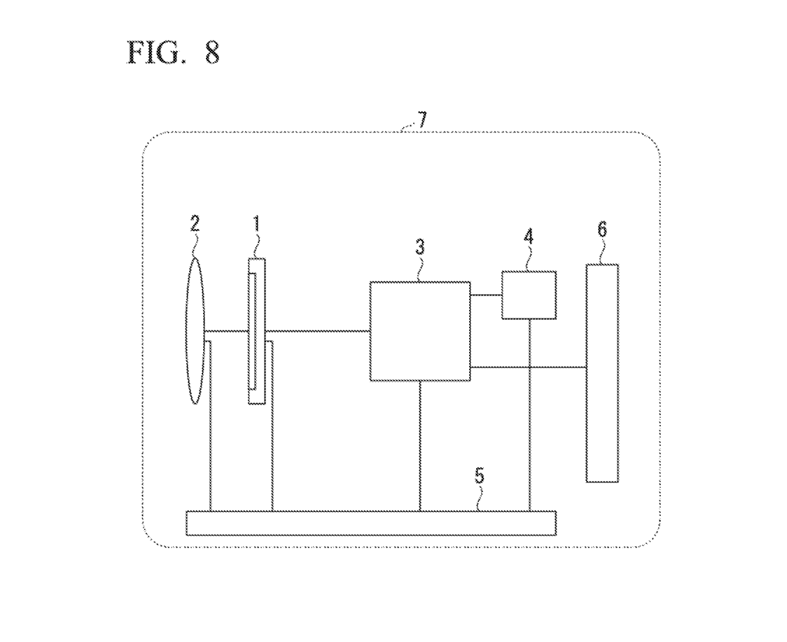

FIG. 8 shows a configuration of an imaging apparatus 7 according to a fourth embodiment of the present invention. The imaging apparatus 7 may be any electronic device having an imaging function. For example, the imaging apparatus 7 is any one of a digital camera, a digital video camera an endoscope, and a microscope. As shown in FIG. 8, the imaging apparatus 7 has the solid-state imaging device 1, a lens unit 2, an image signal processing device 3, a recording device 4, a camera control device 5, and a display device 6.

The solid-state imaging device 1 is any one of the solid-state imaging device 1a of the first embodiment, the solid-state imaging device 1b of the second embodiment, and the solid-state imaging device 1c of the third embodiment. The lens unit 2 has a zoom lens and a focus lens. The lens unit 2 forms a subject image based on light from a subject on a light receiving surface of the solid-state imaging device 1. The image of the light received through the lens unit 2 is formed on the light receiving surface of the solid-state imaging device 1. The solid-state imaging device 1 converts the subject image formed on the light receiving surface into a signal such as an imaging signal, and outputs the signal.

The image signal processing device 3 performs predetermined processing on the signal which is output from the solid-state imaging device 1. The processing performed by the image signal processing device 3 includes conversion to image data, various corrections of image data, compression of image data, and the like.

The recording device 4 has a semiconductor memory or the like for recording or reading image data. The recording device 4 can be attached to and detached from the imaging apparatus 7. The display device 6 displays the image data processed by the image signal processing device 3 or the image based on the image data which is read from the recording device 4.

The camera control device 5 controls the entire imaging apparatus 7. The operation of the camera control device 5 is defined in the program stored in the ROM built into the imaging apparatus 7. The camera control device 5 reads this program, and performs various kinds of control in accordance with the contents defined by the program.

The imaging apparatus of each aspect of the present invention may exclude a configuration corresponding to at least one of the lens unit 2, the image signal processing device 3, the recording device 4, the camera control device 5, and the display device 6.

According to the fourth embodiment, the imaging apparatus 7 having the solid-state imaging device 1 is formed. The solid-state imaging device 1 has a first substrate 10 and a second substrate 20 in any one of the first to third embodiments. Therefore, it is possible to reduce variations in signals due to the positional deviation between the first substrate 10 and the second substrate 20.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description and is only limited by the scope of the appended claims.

1. A solid-state imaging device, comprising:
a first substrate that has a plurality of first photoelectric conversion units into which first light is incident, where the plurality of first photoelectric conversion units converts the first light into a signal; and
a second substrate that has a second semiconductor layer onto which second light is incident, where the second semiconductor layer has a plurality of second photoelectric conversion units into which the second light incident onto the second semiconductor layer is incident, the plurality of second photoelectric conversion units converts the second light into a signal, and the second light is the first light transmitted through the plurality of first photoelectric conversion units,
wherein a first dimension of a first range is smaller than a second dimension of a second range, the first range is the entirety of the second photoelectric conversion unit, the first dimension is a dimension of the first range in a direction parallel to a main surface of the second substrate, the second range is a range in which the second light is incident in the second semiconductor layer, and the second dimension is a dimension of the second range in the direction parallel to the main surface of the second substrate.

2. A solid-state imaging device, comprising:
a first substrate that has a plurality of first photoelectric conversion units into which first light is incident, where the plurality of first photoelectric conversion units converts the first light into a signal; and
a second substrate that has a plurality of second photoelectric conversion units into which second light is incident, where the plurality of second photoelectric conversion units converts the second light into a signal, and the second light is the first light transmitted through the plurality of first photoelectric conversion units,
wherein the first substrate or the second substrate further has a light blocking layer through which a plurality of opening portions is formed, the light blocking layer reflects a part of the second light transmitted through the first photoelectric conversion units, the second light from which the light reflected by the light blocking layer is excluded passes through the plurality of opening portions, and the second light passing through the plurality of opening portions is incident into the plurality of second photoelectric conversion units, and
wherein a first dimension of a first range is smaller than a second dimension of a second range, the first range is a range in which the second light is incident into the second photoelectric conversion units, the first dimension is a dimension of the first range in a direction parallel to a main surface of the second substrate, the second range is the entirety of the second photoelectric conversion unit, and the second dimension is a dimension of the second range in the direction parallel to the main surface of the second substrate.

3. The solid-state imaging device according to claim 1, wherein in a case where the first range and the second range are viewed in a direction perpendicular to the main surface of the second substrate, the first range is within the second range.

4. The solid-state imaging device according to claim 2,
wherein the second substrate has the light blocking layer, and
wherein in a case where the plurality of second photoelectric conversion units and the plurality of opening portions are viewed in a direction perpendicular to the main surface of the second substrate, a center of an area, in which each of the plurality of second photoelectric conversion units overlaps with each of the plurality of opening portions, substantially coincides with a center of each of the plurality of second photoelectric conversion units.

5. The solid-state imaging device according to claim 2,
wherein the first substrate has the light blocking layer, and
wherein in a case where the plurality of first photoelectric conversion units and the plurality of opening portions are viewed in a direction perpendicular to the main surface of the first substrate, a center of an area, in which each of the plurality of first photoelectric conversion units overlaps with each of the plurality of opening portions, substantially coincides with a center of each of the plurality of first photoelectric conversion units.

6. The solid-state imaging device according to claim 2, wherein the second substrate is a front-side illumination type imaging element, the second substrate has a second semiconductor layer and a second wiring layer, the second semiconductor layer has the plurality of second photoelectric conversion units, and the second wiring layer includes the light blocking layer.

2. The solid-state imaging device according to claim 2, wherein the first substrate is a backside illumination type imaging element, the first substrate has a first semiconductor layer and a first wiring layer, the first semiconductor layer has the plurality of first photoelectric conversion units, and the first wiring layer includes the light blocking layer.

8. An imaging apparatus, comprising the solid-state imaging device according to claim 1.

9. An imaging apparatus, comprising the solid-state imaging device according to claim 2.
